(19) United States
(12) Patent Application Publication
(10) Pub. No.: US 2016/0071866 A1
(43) Pub. Date: Mar. 10, 2016

(54) SEMICONDUCTOR MEMORY DEVICE

(71) Applicant: Kabushiki Kaisha Toshiba, Minato-ku (JP)

(72) Inventors: Yoshiro SHIMOJO, Yokkaichi (JP); Masaru KIDOH, Yokkaichi (JP); Masaru KITO, Kuwana (JP); Ryota KATSUMATA, Yokkaichi (JP); Yoshihiro YANAI, Yokkaichi (JP)

(73) Assignee: Kabushiki Kaisha Toshiba, Minato-ku (JP)

(21) Appl. No.: 14/818,603

(22) Filed: Aug. 5, 2015

(30) Foreign Application Priority Data
Sep. 4, 2014 (JP) 2014-180503

(51) Int. Cl. H01L 27/115; H01L 27/02

(52) U.S. Cl. CPC H01L 27/11578; H01L 27/0207; H01L 27/1157

(57) ABSTRACT

According to one embodiment, the first columnar part includes a first channel body and a first charge storage film. The second columnar part includes a second channel body and a second charge storage film. The second columnar part is provided adjacent in the first direction to the first columnar part. The connection part connects a lower end of the first channel body and a lower end of the second channel body. Each of the source layers is connected to an upper end of the first columnar part. Each of the bit lines is connected to an upper end of the second columnar part of every (n+1)-th memory string of a plurality of memory strings arranged in the first direction.

### CROSS-REFERENCE TO RELATED APPLICATION

This application is based upon and claims the benefit of priority from Japanese Patent Application No. 2014-180503, filed on Sep. 4, 2014; the entire contents of which are incorporated herein by reference.

### FIELD

Embodiments described herein relate generally to a semiconductor memory device.

### BACKGROUND

A memory device of the following three-dimensional structure has been proposed. The memory device includes a multilayer body. The multilayer body includes a plurality of electrode layers stacked via insulating layers. The electrode layer serves as a control gate in a memory cell. A memory hole is formed in the multilayer body. A silicon body serving as a channel is provided on the sidewall of the memory hole via a charge storage film.

The write throughput in such a three-dimensional memory device depends on the number of memory strings connected to one bit line.

### BRIEF DESCRIPTION OF THE DRAWINGS

FIG. 1 is a schematic plan view of a semiconductor memory device of an embodiment;

FIG. 2 is a schematic plan view of the semiconductor memory device of the embodiment;

FIG. 3 is a schematic sectional view of the semiconductor memory device of the embodiment;

FIG. 4 is an enlarged schematic sectional view of part of a columnar part of the semiconductor memory device of the embodiment;

FIG. 5 is a schematic plan view of the semiconductor memory device of the embodiment;

FIG. 6 is a schematic plan view of the semiconductor memory device of the embodiment; and

FIG. 7 is a schematic plan view of the semiconductor memory device of the embodiment.

### DETAILED DESCRIPTION

According to one embodiment, a semiconductor memory device includes a multilayer body, a plurality of memory strings, a plurality of source layers, and a plurality of bit lines. The multilayer body includes a plurality of electrode layers stacked via an insulating layer. The memory strings are arranged in a first direction and a second direction. The first direction is orthogonal to a stacking direction of the multilayer body, and the second direction is orthogonal to the stacking direction and the first direction. The source layers extend in the second direction on the memory string and are separated in the first direction. The bit lines extend in the first direction on the memory string and are separated in the second direction. Each of the memory strings includes a first columnar part, a second columnar part, and a connection part. The first columnar part includes a first channel body extending in the stacking direction, and a first charge storage film provided between the first channel body and the electrode layers. The second columnar part includes a second channel body extending in the stacking direction, and a second charge storage film provided between the second channel body and the electrode layer. The second columnar part is provided adjacent in the first direction to the first columnar part. The connection part connects a lower end of the first channel body and a lower end of the second channel body. Each of the source layers is connected to an upper end of the first columnar part. Each of the bit lines is connected to an upper end of the second columnar part of every (n+1)-th memory string (n being an integer of 1 or more) of a plurality of memory strings arranged in the first direction.

Embodiments will now be described with reference to the drawings. In the drawings, like elements are labeled with like reference numerals.

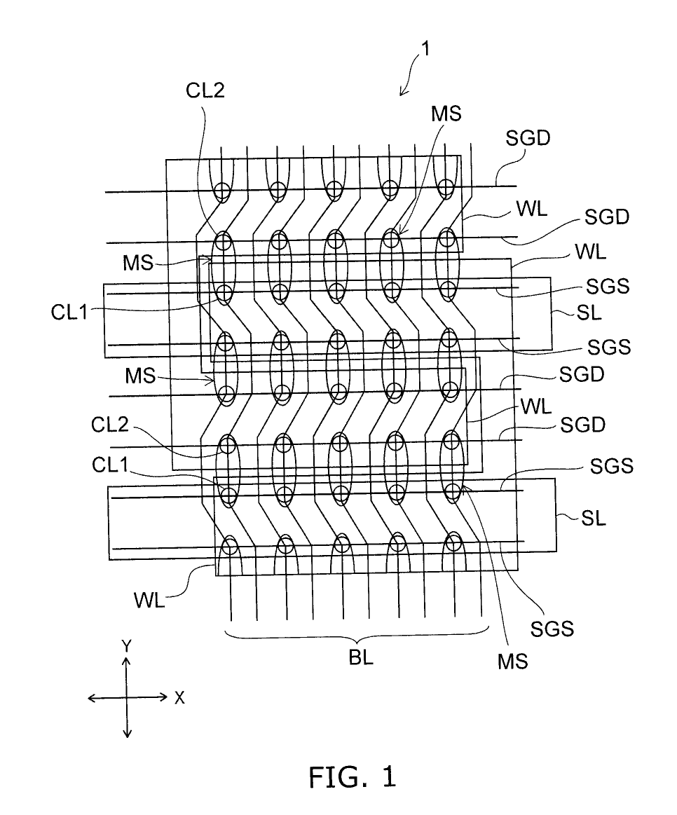

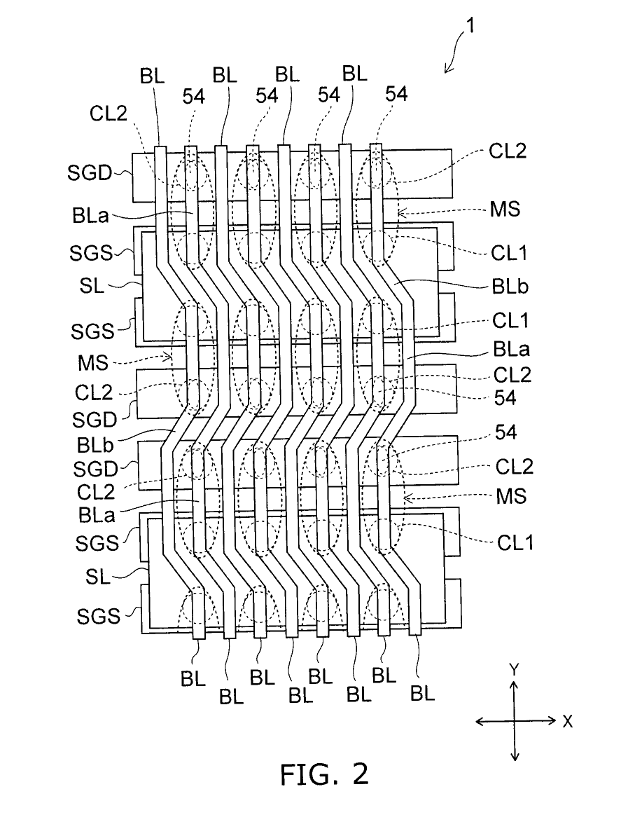

FIGS. 1 and 2 are schematic plan views of a memory cell array 1 of a semiconductor memory device of a first embodiment.

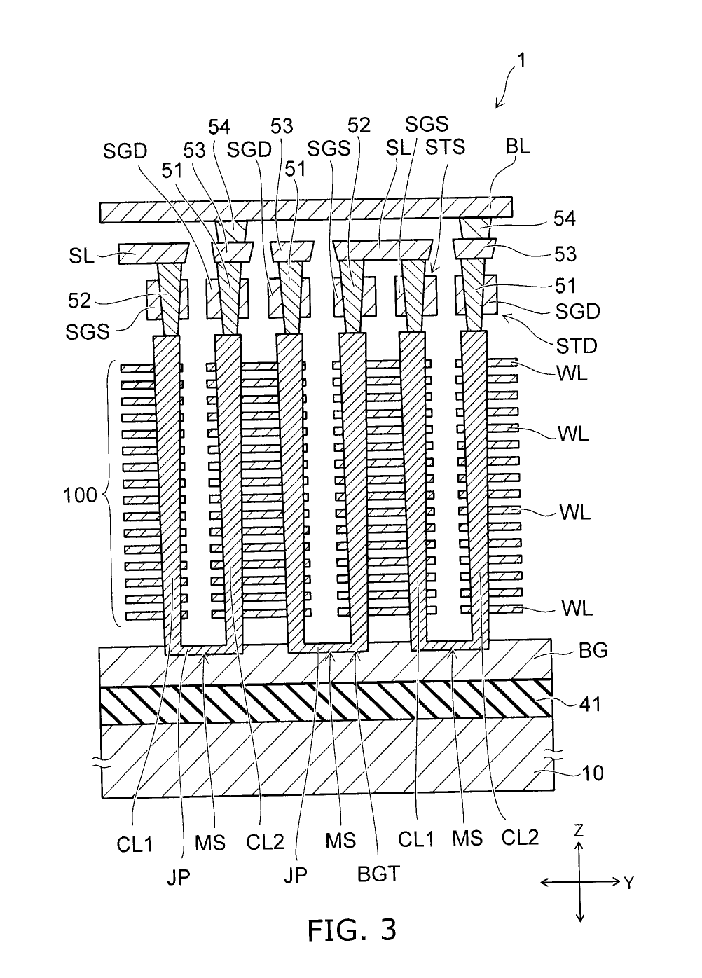

FIG. 3 is a schematic sectional view of the memory cell array 1. Illustration of interelectrode insulating layers, insulating separation films, interlayer insulating films and the like is omitted in FIG. 3.

A multilayer body 100 including a plurality of electrode layers WL is provided on a substrate 10. Two directions orthogonal to each other in a plane parallel to the major surface of the substrate 10 are referred to as X-direction and Y-direction. The direction orthogonal to the X-direction and the Y-direction (XY-plane) is referred to as Z-direction (stacking direction). The plurality of electrode layers WL are stacked in the Z-direction.

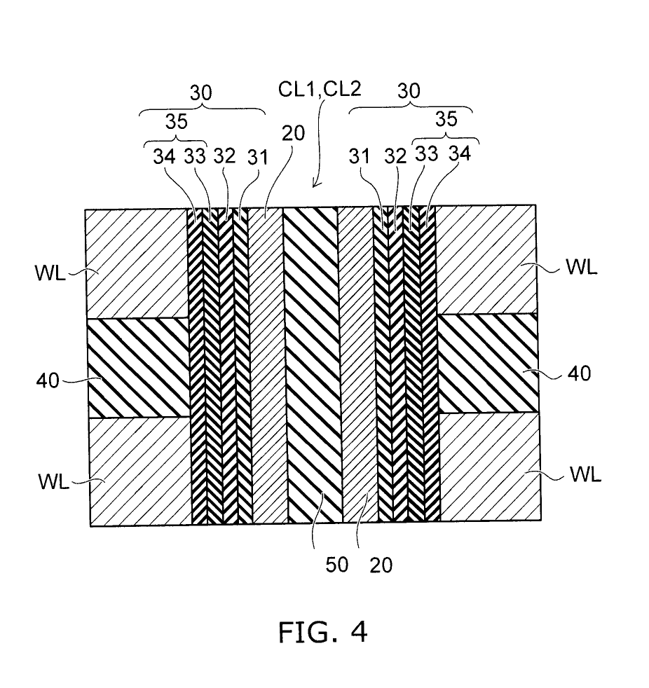

The memory cell array 1 includes the multilayer body 100. A plurality of electrode layers WL and insulating layers 40 (shown in FIG. 4) are alternately stacked in the multilayer body 100. The insulating layer 40 is provided between the electrode layers WL adjacent in the stacking direction (Z-direction). As shown in FIG. 3, the multilayer body 100 is provided on a back gate BG. The back gate BG serves as a lower gate layer. The number of electrode layers WL shown in the figures is illustrative only. The number of electrode layers WL is arbitrary.

The back gate BG is provided on the substrate 10 via an insulating layer 41. The back gate BG and the electrode layer WL are layers composed primarily of silicon. Furthermore, the back gate BG and the electrode layer WL contain e.g. boron as an impurity for imparting conductivity to the silicon layer. The electrode layer WL may include metal silicide. The insulating layer 40 primarily includes e.g. silicon oxide.

The memory cell array 1 includes a plurality of memory strings MS. One memory string MS is formed in a U-shape. The memory string MS includes a pair of a first columnar part CL1 and a second columnar part CL2 extending in the Z-direction, and a connection part JP connecting the respective lower ends of the first columnar part CL1 and the second columnar part CL2. The first columnar part CL1 and the second columnar part CL2 are each formed like e.g. a circular or elliptic cylinder, and penetrate through the multilayer body 100 to the back gate BG.

A drain side columnar part 51 and a drain side select gate SGD are provided on the second columnar part CL2 in the U-shaped memory string MS. A source side columnar part 52 and a source side select gate SGS are provided on the first columnar part CL1.

The drain side columnar part 51 penetrates through the drain side select gate SGD to the upper end of the second columnar part CL2. The source side columnar part 52 penetrates through the source side select gate SGS to the upper end of the first columnar part CL1.

The drain side select gate SGD and the source side select gate SGS are layers composed primarily of silicon. Furthermore, the drain side select gate SGD and the source side select gate SGS contain e.g. boron as an impurity for imparting conductivity to the silicon layer.

The drain side select gate SGD and the source side select gate SGS serve as upper select gate layers. The back gate BG serves as a lower select gate layer. The drain side select gate SGD, the source side select gate SGS, and the back gate BG are thicker than one electrode layer WL.

The drain side select gate SGD and the source side select gate SGS are separated in the Y-direction. As shown in FIGS. 1 and 2, the drain side select gate SGD and the source side select gate SGS extend in the X-direction.

The multilayer body 100 including a plurality of electrode layers WL is separated in the Y-direction between the first columnar part CL1 and the second columnar part CL2.

A source layer SL is provided on the source side columnar part 52. The source layer SL is connected to the source side columnar part 52.

An interconnection layer 53 is provided on the drain side columnar part 51. A bit line contact part 54 is provided on the interconnection layer 53. The interconnection layer 53 is provided in the same layer as the source layer SL. A bit line BL is provided on the interconnection layer 53 and the source layer SL. The bit line BL is connected to the drain side columnar part 51 through the bit line contact part 54 and the interconnection layer 53.

FIG. 4 is an enlarged schematic sectional view of part of the first columnar part CL1 and the second columnar part CL2. The first columnar part CL1 and the second columnar part CL2 have the same configuration.

The columnar part CL1, CL2 includes a channel body 20 and a memory film 30 provided sequentially from the central axis side toward the radial outside. The channel body 20 is e.g. a silicon film. The impurity concentration of the channel body 20 is lower than the impurity concentration of the electrode layer WL.

The memory film 30 includes a block insulating film 35, a charge storage film 32, and a tunnel insulating film 31. The block insulating film 35, the charge storage film 32, and the tunnel insulating film 31 are provided sequentially from the electrode layer WL side between the electrode layer WL and the channel body 20.

The channel body 20 is provided like a pipe extending in the stacking direction of the multilayer body 100. The memory film 30 is provided like a pipe so as to surround the outer peripheral surface of the channel body 20. The memory film 30 extends in the stacking direction of the multilayer body 100. The electrode layer WL surrounds the channel body 20 via the memory film 30. A core insulating film 50 is provided inside the channel body 20. The core insulating film 50 is e.g. a silicon oxide film.

The block insulating film 35 is in contact with the electrode layer WL. The tunnel insulating film 31 is in contact with the channel body 20. The charge storage film 32 is provided between the block insulating film 35 and the tunnel insulating film 31.

The channel body 20 functions as a channel in the memory cell. The electrode layer WL functions as a control gate of the memory cell. The charge storage film 32 functions as a data storage layer for storing charge injected from the channel body 20. That is, a memory cell is formed in the crossing portion of the channel body 20 and each electrode layer WL. The memory cell has a structure in which the channel is surrounded with the control gate.

The semiconductor memory device of the embodiment is a non-volatile semiconductor memory device capable of electrically and freely erasing/writing data and retaining its memory content even when powered off.

The memory cell is a memory cell of e.g. the charge trap type. The charge storage film 32 includes a large number of trap sites for trapping charge. The charge storage film 32 is e.g. a silicon nitride film.

The tunnel insulating film 31 serves as a potential barrier when charge is injected from the channel body 20 into the charge storage film 32, or when the charge stored in the charge storage film 32 is diffused into the channel body 20. The tunnel insulating film 31 is e.g. a silicon oxide film.

Alternatively, the tunnel insulating film may be a multilayer film (ONO film) of the structure in which a silicon nitride film is interposed between a pair of silicon oxide films. With the tunnel insulating film made of ONO film, the erase operation can be performed with a lower electric field than with a monolayer silicon oxide film.

The block insulating film 35 prevents the charge stored in the charge storage film 32 from diffusing into the electrode layer WL. The block insulating film 35 includes a cap film 34 and a block film 33. The cap film 34 is provided in contact with the electrode layer WL. The block film 33 is provided between the cap film 34 and the charge storage film 32.

The block film 33 is e.g. a silicon oxide film. The cap film 34 is a film having higher dielectric constant than silicon oxide. The cap film 34 is e.g. a silicon nitride film. The cap film 34 thus provided in contact with the electrode layer WL can suppress back-tunneling electrons injected from the electrode layer WL at erase time. That is, charge blocking performance can be improved by using a multilayer film of silicon oxide film and silicon nitride film as the block insulating film 35.

As shown in FIG. 3, a drain side select transistor STD is provided on the second columnar part CL2 in the U-shaped memory string MS. A source side select transistor STS is provided on the first columnar part CL1.

The drain side select transistor STD and the source side select transistor STS are vertical transistors in which the current flows in the stacking direction (Z-direction) of the multilayer body 100.

The drain side select gate SGD surrounds the drain side columnar part 51 and functions as a gate electrode of the drain side select transistor STD. The drain side columnar part 51 includes a tubular channel connected to the channel body 20 of the second columnar part CL2, and a gate insulating film provided between the channel and the drain side select gate SGD. The channel of the drain side select transistor STD is connected to the bit line BL through the interconnection layer 53 and the bit line contact part 54.

The source side select gate SGS surrounds the source side columnar part 52 and functions as a gate electrode of the source side select transistor STS. The source side columnar part 52 includes a tubular channel connected to the channel body 20 of the first columnar part CL1, and a gate insulating film provided between the channel and the source side select gate SGS. The channel of the source side select transistor STS is connected to the source layer SL.

A back gate transistor BGT is provided in the connection part JP of the memory string MS. The back gate BG functions as a gate electrode of the back gate transistor BGT. The memory film 30 provided in the back gate BG functions as a gate insulating film of the back gate transistor BGT.

A plurality of memory cells are provided between the drain side select transistor STD and the back gate transistor BGT. In each memory cell MC, the electrode layer WL serves as a control gate. Likewise, a plurality of memory cells are provided also between the back gate transistor BGT and the source side select transistor STS. In each memory cell MC, the electrode layer WL serves as a control gate.

The plurality of memory cells, the drain side select transistor STD, the back gate transistor BGT, and the source side select transistor STS are series connected through the channel body 20 to constitute one U-shaped memory string MS. This memory string MS is arranged in a plurality in the X-direction and the Y-direction. Thus, a plurality of memory cells are provided three-dimensionally in the X-direction, the Y-direction, and the Z-direction.

As shown in FIG. 1, each electrode layer WL is processed into a comb-shaped pattern having a plurality of fingers extending in the X-direction. For instance, two comb-shaped patterns are combined into one memory cell array.

The finger of one comb-shaped pattern is located between the plurality of fingers of the other comb-shaped pattern. The plurality of fingers of two comb-shaped patterns are arranged with spacing in the Y-direction.

The columnar part CL1, CL2 of the memory string described above is formed in the finger of the electrode layer WL. A plurality of columnar parts CL1, CL2 are arranged in e.g. a square lattice configuration in the X-direction and the Y-direction.

The direction connecting the first columnar part CL1 and the second columnar part CL2 belonging to the same single memory string MS is parallel to the Y-direction. The first columnar part CL1 and the second columnar part CL2 belonging to the same single memory string MS are formed in the fingers of different comb-shaped patterns.

An insulating separation film (slit) is interposed between the first columnar part CL1 and the second columnar part CL2 belonging to the same single memory string MS. Thus, the control gate (electrode layer WL) of the memory cell formed in the first columnar part CL1 and the control gate (electrode layer WL) of the memory cell formed in the second columnar part CL2 located across the insulating separation film (slit) can be controlled independently by different comb-shaped patterns.

As shown in FIG. 2, a plurality of source layers SL extend in the X-direction on the memory string MS and separated in the Y-direction.

The source side select gate SGS extends in the X-direction below the source layer SL. In the region not provided with the source layer SL, the interconnection layer 53 shown in FIG. 3 is provided in the same layer as the source layer SL. The drain side select gate SGD extends in the X-direction below the interconnection layer 53.

As shown in FIG. 2, a plurality of bit lines BL extend in the Y-direction on the memory string MS and separated in the X-direction.

Each bit line BL is connected through the bit line contact part 54 to the upper end of the second columnar part CL2 of every (n+1)-th memory string MS (n being an integer of 1 or more) of a plurality of memory strings MS arranged in the Y-direction.

In the example shown in FIG. 2, each bit line BL is connected through the bit line contact part 54 to the upper end of the second columnar part CL2 of every other memory string MS of a plurality of memory strings MS arranged in the Y-direction.

According to the embodiment, the number of memory strings MS connected to one bit line BL is smaller than that in the configuration in which each bit line BL is connected to the second columnar part CL2 of all the memory strings MS of the same row arranged in the Y-direction. This can improve the processing performance, particularly the write throughput.

Each bit line BL includes a first portion BLa parallel to the Y-direction and a second portion BLb inclined with respect to the Y-direction and the X-direction. The first portions BLa and the second portions BLb are connected alternately in the Y-direction.

The first portion BLa is located on the memory string MS. Furthermore, the first portion BLa is located on the region between the memory strings MS arranged in the X-direction. The second portion BLb is located on the region between the memory strings MS arranged in the Y-direction.

The X-direction pitch of the bit line contact parts 54 is larger than the X-direction pitch of the first portions BLa of the bit lines BL.

The upper limit of the diameter of the columnar part CL2 can be allowed up to approximately twice the width of the bit line BL. The X-direction width of the bit line contact part 54 is nearly equal to the width of the bit line BL.

The columnar part CL1, CL2 is formed in a memory hole. The memory hole is formed in the multilayer body 100 by e.g. RIE (reactive ion etching) technique.

The resist used as a processing mask for the multilayer body 100 is subjected to exposure transfer of the latent image of a plurality of line-and-space patterns extending in the X-direction. Furthermore, the resist is subjected to exposure transfer of the latent image of a plurality of line-and-space patterns extending in the Y-direction orthogonal to the X-direction. The exposure amount is larger in the crosspoint of the orthogonal line pattern latent images than in the line portion. The crosspoint of the orthogonal space pattern latent images is not subjected to exposure. The crosspoints of the line pattern latent images or the crosspoints of the space pattern latent images are made soluble in the developer liquid.

Thus, after developing the resist, a plurality of holes (openings) arranged in a square lattice configuration in the X-direction and the Y-direction are formed in the resist. The resist is used as a mask to etch the multilayer body 100 by RIE technique. Thus, a plurality of memory holes arranged in a square lattice configuration in the X-direction and the Y-direction can be formed.

The aforementioned light exposure can utilize crosspoint exposure with orthogonal line-and-space patterns. Thus, the position and shape of a plurality of memory holes can be controlled with high accuracy. Accordingly, short circuit failure is less likely to occur between the adjacent columnar parts CL1, CL2.

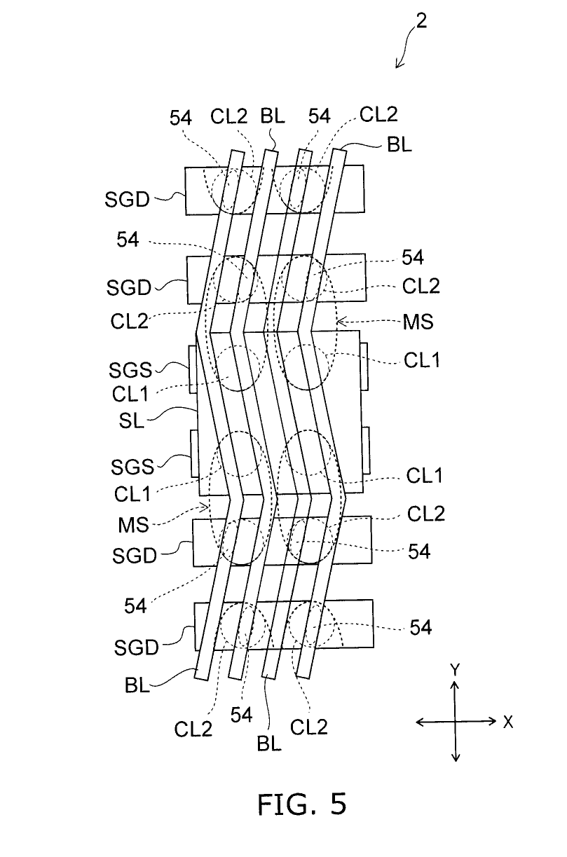

FIG. 5 is a schematic plan view of a memory cell array 2 of a semiconductor memory device of a second embodiment.

The second embodiment is different from the first embodiment in the layout of the bit line BL.

Also in the second embodiment, each bit line BL is connected through the bit line contact part 54 to the upper end of the second columnar part CL2 of every (n+1)-th memory string MS (n being an integer of 1 or more) of a plurality of memory strings MS arranged in the Y-direction.

In the example shown in FIG. 5, each bit line BL is connected through the bit line contact part 54 to the upper end of the second columnar part CL2 of every other memory string MS of a plurality of memory strings MS arranged in the Y-direction.

Thus, also in the second embodiment, the number of memory strings MS connected to one bit line BL is smaller than that in the configuration in which each bit line BL is connected to the second columnar part CL2 of all the memory strings MS of the same row arranged in the Y-direction. This can improve the processing performance, particularly the write throughput.

According to the second embodiment, each bit line BL extends in the Y-direction with zigzag bends. The lines inclined with respect to the X-direction and the Y-direction are continued zigzag in the Y-direction.

The bit line BL extends at a position displaced from the center of the second columnar part CL2. The center of the second columnar part CL2 is displaced from the center of the bit line contact part 54.

The X-direction pitch of the bit line contact parts 54 is larger than the pitch in the width direction of the bit lines BL.

In a plurality of memory strings MS arranged in the Y-direction, a plurality of bit line contact parts 54 are not arranged in a row in the Y-direction. The X-direction positions of the bit line contact parts 54 adjacent in the Y-direction are displaced from each other between the bit lines BL adjacent in the X-direction.

In the first embodiment, as shown in FIG. 2, the bit line BL is bent in a narrow region between the memory strings MS adjacent in the Y-direction. The light exposure margin of the interconnection bent in a narrow region is small. The region in which the interconnection is bent needs to be wider to some extent in order to ensure a sufficient margin. This may result in increasing the cell array area.

In contrast, according to the second embodiment, the bit line BL is bent in a region with a larger margin in the Y-direction than in the first embodiment. Thus, the light exposure margin of the bit line can be sufficiently ensured. This can suppress useless increase of cell array area.

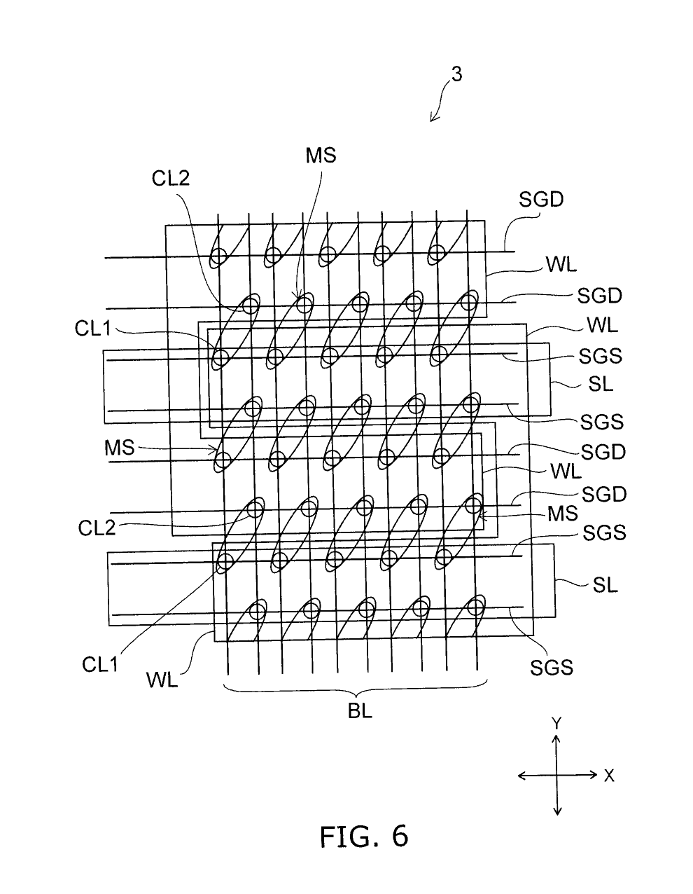

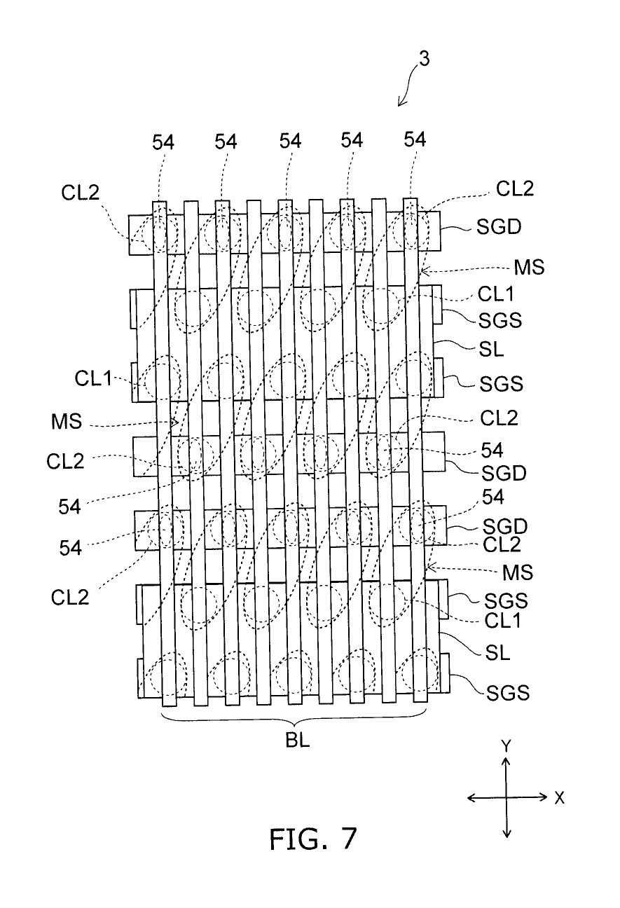

FIGS. 6 and 7 are schematic plan views of a memory cell array 3 of a semiconductor memory device of a third embodiment.

According to the third embodiment, a plurality of columnar parts CL1, CL2 are arranged in a staggered configuration or a hexagonal close-packed configuration. Between the row in which a plurality of columnar parts CL1, CL2 are arranged in the Y-direction and its adjacent row, the Y-direction positions of the columnar parts CL1, CL2 are displaced from each other. Between the row in which a plurality of columnar parts CL1, CL2 are arranged in the X-direction and its adjacent row, the X-direction positions of the columnar parts CL1, CL2 are displaced from each other.

The first columnar parts CL1 and the second columnar parts CL2 respectively belonging to different memory strings MS are arranged alternately in the Y-direction. The direction connecting the first columnar part CL1 and the second columnar part CL2 belonging to the same memory string MS is inclined with respect to the X-direction and the Y-direction.

A plurality of bit lines BL are separated in the X-direction. Each bit line BL extends straight in the Y-direction.

The first columnar part CL1 and the second columnar part CL2 belonging to the same memory string MS are respectively located below different bit lines BL adjacent in the X-direction.

Each bit line BL is connected through the bit line contact part 54 to the upper end of the second columnar part CL2 of every other memory string MS of a plurality of memory strings MS arranged in the Y-direction.

The X-direction pitch of the bit line contact parts 54 is larger than the X-direction pitch of the bit lines BL.

Also in the third embodiment, the number of memory strings MS connected to one bit line BL is smaller than that in the configuration in which each bit line BL is connected to the second columnar part CL2 of all the memory strings MS of the same row arranged in the Y-direction. This can improve the processing performance, particularly the write throughput.

In the above embodiments, the drain side select gates SGD adjacent in the Y-direction can be integrated together. The source side select gates SGS adjacent in the Y-direction can be integrated together.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a multilayer body including a plurality of electrode layers stacked via an insulating layer;
a plurality of memory strings arranged in a first direction and a second direction, the first direction being orthogonal to a stacking direction of the multilayer body, and the second direction being orthogonal to the stacking direction and the first direction;
a plurality of source layers extending in the second direction on the memory string and separated in the first direction; and
a plurality of bit lines extending in the first direction on the memory string and separated in the second direction,
each of the memory strings including:
a first columnar part including a first channel body extending in the stacking direction, and a first charge storage film provided between the first channel body and the electrode layers;
a second columnar part including a second channel body extending in the stacking direction, and a second charge storage film provided between the second channel body and the electrode layer, the second columnar part being provided adjacent in the first direction to the first columnar part; and
a connection part connecting a lower end of the first channel body and a lower end of the second channel body,
each of the source layers being connected to an upper end of the first columnar part, and
each of the bit lines being connected to an upper end of the second columnar part of every (n+1)-th memory string (n being an integer of 1 or more) of a plurality of memory strings arranged in the first direction.

2. The device according to claim 1, wherein the bit lines include first portions parallel to the first direction, and second portions inclined with respect to the first direction.

3. The device according to claim 2, wherein
the first portions are located on the memory strings, and
the second portions are located in regions between the memory strings arranged in the first direction.

4. The device according to claim 1, wherein the bit lines extend in the first direction with zigzag bend.

5. The device according to claim 4, wherein a center of the second columnar part is displaced from a center of a contact part in which the second columnar part is connected to one bit line.

6. The device according to claim 5, wherein positions in the second direction of a plurality of contact parts are displaced from each other between the bit lines adjacent in the second direction.

7. The device according to claim 1, wherein a plurality of first columnar parts and a plurality of second columnar parts are arranged in a square lattice configuration in the first direction and the second direction.

8. The device according to claim 1, wherein one memory string includes:
a source side select gate provided between the first columnar part and the source layer, and extending in the second direction; and
a drain side select gate provided between the second columnar part and the bit line, and extending in the second direction.

9. The device according to claim 8, wherein one memory string includes:
a source side columnar part penetrating through the source side select gate, and connected to the first columnar part and the source layer; and
a drain side columnar part penetrating through the drain side select gate, and connected to the second columnar part and the bit line.

10. The device according to claim 9, further comprising:
an interconnection layer provided between the drain side columnar part and the bit line, and connected to the drain side columnar part and the bit line.

11. The device according to claim 10, wherein the interconnection layer is provided in a same layer as the source layer.

12. A semiconductor memory device comprising:
a multilayer body including a plurality of electrode layers stacked via an insulating layer;
a plurality of memory strings arranged in a first direction and a second direction, the first direction being orthogonal to a stacking direction of the multilayer body, and the second direction being orthogonal to the stacking direction and the first direction;
a plurality of source layers extending in the second direction on the memory string and separated in the first direction; and
a plurality of bit lines extending in the first direction on the memory string and separated in the second direction,
each of the memory strings including:
a first columnar part including a first channel body extending in the stacking direction, and a first charge storage film provided between the first channel body and the electrode layer;
a second columnar part including a second channel body extending in the stacking direction, and a second charge storage film provided between the second channel body and the electrode layer; and
a connection part connecting a lower end of the first channel body and a lower end of the second channel body,
the first columnar part and the second columnar part of different ones of the memory strings being arranged alternately in the first direction,
each of the source layers being connected to an upper end of the first columnar part, and
each of the bit lines being connected to an upper end of the second columnar part of every other memory string of a plurality of memory strings arranged in the first direction.

13. The device according to claim 12, wherein the first columnar part and the second columnar part belonging to a same memory string are respectively located below different ones of the bit lines adjacent in the second direction.

14. The device according to claim 12, wherein a direction connecting the first columnar part and the second columnar part belonging to a same memory string is inclined with respect to the first direction and the second direction.

15. The device according to claim 12, wherein the bit line extends straight in the first direction.

16. The device according to claim 12, wherein one memory string includes:
a source side select gate provided between the first columnar part and the source layer, and extending in the second direction; and
a drain side select gate provided between the second columnar part and the bit line, and extending in the second direction.

17. The device according to claim 16, wherein one memory string includes:
a source side columnar part penetrating through the source side select gate, and connected to the first columnar part and the source layer; and
a drain side columnar part penetrating through the drain side select gate, and connected to the second columnar part and the bit line.

18. The device according to claim 17, further comprising:
an interconnection layer provided between the drain side columnar part and the bit line, and connected to the drain side columnar part and the bit line.

19. The device according to claim 18, wherein the interconnection layer is provided in a same layer as the source layer.
